(19) United States
(12) Patent Application Publication
(10) Pub. No.: US 2024/0222069 A1
(43) Pub. Date: Jul. 4, 2024

(54) METHOD FOR OPERATING A MULTI-BEAM PARTICLE MICROSCOPE IN A CONTRAST OPERATING MODE WITH DEFOCUSED BEAM GUIDING, COMPUTER PROGRAM PRODUCT AND MULTI-BEAM PARTICLE MICROSCOPE

(71) Applicant: Carl Zeiss MultiSEM GmbH, Oberkochen (DE)

(72) Inventor: Stefan Schubert, Oberkochen (DE)

(21) Appl. No.: 18/605,106

(22) Filed: Mar. 14, 2024

Related U.S. Application Data
(63) Continuation of application No. PCT/EP22/25403, filed on Aug. 31, 2022.

(30) Foreign Application Priority Data
Sep. 17, 2021 (DE) 10 2021 124 099.9

(51) Int. Cl. H01J 37/28; H01J 37/244

(52) U.S. Cl. CPC H01J 37/28; H01J 37/244; H01J 2237/24465; H01J 2237/24495

(57) ABSTRACT

A method for operating a multi-beam particle microscope in a contrast operating mode, comprises: irradiating an object with a multiplicity of charged first individual particle beams, each first individual particle beam irradiating a separate individual field region of the object in a scanning fashion; collecting second individual particle beams emerging or emanating from the object due to the first individual particle beams; defocused projecting the second individual particle beams onto detection regions of a detection unit so that the second individual particle beams emerging or emanating from two different individual field regions are projected onto different detection regions, a plurality of detection channels being assigned to each detection region, the detection channels each encoding angle information and/or direction information of the second individual particle beams when starting from the object; and generating individual images of each individual field region based on data obtained via signals from each detection region.

### CROSS-REFERENCE TO RELATED APPLICATIONS

The present application is a continuation of, and claims benefit under 35 USC 120 to, international application No. PCT/EP2022/025403, filed Aug. 31, 2022, which claims benefit under 35 USC 119 of German Application No. 10 2021 124 099.9, filed Sep. 17, 2021. The entire disclosure of each these applications is incorporated by reference herein.

### FIELD

The disclosure relates to a method for operating a multi-beam particle microscope in a contrast operating mode with defocused beam guiding, an associated computer program product, and a multi-beam particle microscope.

### BACKGROUND

With the continuous development of ever smaller and ever more complex microstructures such as semiconductor components, there is a desire to develop and optimize planar production techniques and inspection systems for producing and inspecting small dimensions of the microstructures. By way of example, the development and production of the semiconductor components often involves monitoring of the design of test wafers, and the planar production techniques often involve process optimization for a reliable production with a high throughput. Moreover, there have been recent demands for an analysis of semiconductor wafers for reverse engineering and for a customer-specific, individual configuration of semiconductor components. Therefore, it is desirable to use an inspection mechanism which can be used with a high throughput for examining the microstructures on wafers with great accuracy.

Typical silicon wafers used in the production of semiconductor components have diameters of up to 300 mm. Each wafer is often divided into 30 to 60 repeating regions (“dies”) with a size of up to 800 mm². A semiconductor apparatus typically comprises a plurality of semiconductor structures, which are produced in layers on a surface of the wafer by planar integration techniques. Semiconductor wafers typically have a plane surface on account of the production processes. The structure size of the integrated semiconductor structures in this case can extend from a few μm to the critical dimensions of 5 nm, with the structure sizes becoming even smaller in the near future; in future, structure sizes or critical dimensions are expected to be less than 3 nm, for example 2 nm, or even under 1 nm. In the case of the aforementioned small structure sizes, it can be desirable to quickly identify defects in the size of the critical dimensions in a very large area. For several applications, the desired accuracy of a measurement provided by inspection equipment is even higher, for example by a factor of two or one order of magnitude. By way of example, it can be desirable to measure a width of a semiconductor feature with an accuracy of below 1 nm, for example 0.3 nm or even less, and a relative position of semiconductor structures is to be determined with an overlay accuracy of below 1 nm, for example 0.3 nm or even less.

The MSEM, a multi-beam scanning electron microscope, is a relatively new development in the field of charged particle systems (charged particle microscopes, CPMs). By way of example, a multi-beam scanning electron microscope is disclosed in U.S. Pat. No. 7,244,949 B2 and in US 2019/0355544 A1. In the case of a multi-beam electron microscope or MSEM, a sample is irradiated simultaneously with a plurality of individual electron beams, which are arranged in a field or grid. By way of example, 4 to 10,000 individual electron beams can be provided as primary radiation, with each individual electron beam being separated from an adjacent individual electron beam by a pitch of 1 to 200 micrometers. By way of example, an MSEM has approximately 100 separate individual electron beams (“beamlets”), which are arranged for example in a hexagonal grid, with the individual electron beams being separated by a pitch of approximately 10 μm. The plurality of charged individual particle beams (primary beams) are focused on a surface of a sample to be examined by way of a common objective lens. By way of example, the sample can be a semiconductor wafer which is fastened to a wafer holder that is mounted on a movable stage. During the illumination of the wafer surface with the charged primary individual particle beams, interaction products, for example secondary electrons or backscattered electrons, emanate from the surface of the wafer. Their start points correspond to those locations on the sample on which the plurality of primary individual particle beams are focused in each case. The amount and the energy of the interaction products generally depends on the material composition and the topography of the wafer surface. The interaction products form a plurality of secondary individual particle beams (secondary beams), which are collected by the common objective lens and which are incident on a detector arranged in a detection plane as a result of a projection imaging system of the multi-beam inspection system. The detector comprises a plurality of detection regions, each of which comprises a plurality of detection pixels, and the detector captures an intensity distribution for each of the secondary individual particle beams. An image field of for example 100 μm×100 μm can be obtained in the process.

Certain known multi-beam electron microscopes comprise a sequence of electrostatic and magnetic elements. At least some of the electrostatic and magnetic elements are settable in order to adapt the focus position and the stigmation of the plurality of charged individual particle beams. Such multi-beam systems can moreover comprise at least one cross-over plane of the primary or the secondary charged individual particle beams. Moreover, such systems can comprise detection systems to make the setting easier. Such systems can comprise at least one beam deflector (“deflection scanner”) for collective scanning of a region of the sample surface via the plurality of primary individual particle beams in order to obtain an image field of the sample surface. Further details regarding a multi-beam electron microscope and a method for operating same are described in the German patent application with the application 102020206739.2, filed on May 28, 2020, and in the associated patent family documents, the disclosure of which is fully incorporated by reference in this patent application.

The inspection tasks for which multi-beam electron microscopes, or more generally multi-beam particle microscopes, may satisfy different desired properties depending on the application or sample. By way of example, one objective may be to obtain an overview image of a sample at a high speed (e.g. in a normal operating mode or normal inspection mode). However, it is also possible for regions of a sample that are specifically of interest to be examined more closely. Issues here relate for example to the exact course of edges (topographical contrast or edge contrast), to material boundaries in the sample (material contrast) or to local accumulations of charge on the sample (charge contrast). In a so-called contrast operating mode, a contrast aperture is arranged in the projection path or secondary path of the multi-beam particle microscope in the region of a beam cross-over of the secondary beams (cross-over; pupil plane), and allows the secondary particles starting or emanating from the sample to be filtered according to their starting angles or more generally according to their trajectory. Different contrasts can be examined by selecting and/or combining different contrast apertures. After passing through the contrast aperture(s), the secondary particles or second individual particle beams can strike detection regions of the detector in each case in a focused fashion. Further details in this respect are described for example in DE 2015 202 172 B4, the disclosure of which is fully incorporated by reference in this patent application.

In accordance with certain known technology, it is desirable to effect a plurality of recordings with different settings in order to obtain different contrast information (edge contrast, material contrast, voltage contrast). The settings that are desired for obtaining an edge contrast are generally different than those for obtaining a material contrast or voltage contrast. Moreover, it is generally desirable to further improve contrast recordings.

Martin Kienle, Aufbau und Erprobung eines außeraxialen Vielkanalspektrometers für Sekundärelektronen [Setup and testing of an off-axis multi-channel spectrometer for secondary electrons], dissertation, University of Tübingen, 2002, discloses defocused incidence of secondary particles on a light guide during adjustment of a multi-channel spectrometer.

### SUMMARY

The present disclosure proposes an improved method for operating a multi-beam particle microscope in a contrast operating mode. The method is intended to facilitate and/or improve the generation of contrast information. In addition, the intention is to make it possible, in general, to obtain different contrast information via a single scan/single recording.

The disclosure involves the consideration, inter alia, that the angular spectrum of the secondary particle beams contains contrast information which is not used in the contrast operating modes that have existed hitherto. Instead, this contrast information is lost during the focused imaging of the secondary beams onto the detector. Conversely, the disclosure allows the use of this information from the angular spectrum. To put it another way, the disclosure makes it possible to use not only angle information from the angular spectrum but also direction information. This information can become accessible if the imaging of the secondary particle beams onto a detector intentionally takes place in a defocused, rather than focused, fashion and if different detection channels are assigned to the resultant increasing incidence area on the detector (detection region), the respective signals of the detection channels allowing an evaluation of the angle information and/or direction information.

In accordance with a first aspect of the disclosure, the latter relates to a method for operating a multi-beam particle microscope, the method including the following steps: operating the multi-beam particle microscope in a contrast operating mode, comprising the following steps: irradiating an object with a multiplicity of charged first individual particle beams, wherein each first individual particle beam irradiates a separate individual field region of the object in a scanning fashion; collecting second individual particle beams which emerge or emanate from the object on account of the first individual particle beams; defocused projecting of the second individual particle beams onto detection regions of a detection unit in such a way that the second individual particle beams emerging or emanating from two different individual field regions are projected onto different detection regions, wherein a plurality of detection channels are assigned to each detection region, wherein the detection channels each encode angle information and/or direction information of the second individual particle beams when starting from the object; and generating individual images of each of the individual field regions on the basis of data which are obtained or have been obtained via signals from each of the detection regions with their respectively assigned detection channels.

The first charged individual particle beams can be, for example, electrons, positrons, muons or ions or other charged particles. The individual field regions of the object that are assigned to each first individual particle beam are scanned in a scanning fashion, e.g. line by line or column by column. In this case, the individual field regions can be adjacent to one another or to cover the object or a part thereof in tiling fashion. The individual field regions are substantially separate from one another, but they can also overlap one another in the marginal regions. In this way, it is possible to obtain an image of the object that is as complete and contiguous as possible. The individual field regions can be embodied in rectangular or square fashion since this is the easiest to realize for the scanning process with the aid of particle radiation. The individual field regions can be arranged as rectangles in different lines one above another so as to result overall in a hexagonal structure. The number of particle beams can be 3n (n−1)+1, where n is an arbitrary natural number, in the hexagonal case. Other arrangements of the individual field regions, e.g. in a square or rectangular grid, are likewise possible.

The second individual particle beams can be backscattered electrons or else secondary electrons. In this case, for analysis purposes the low-energy secondary electrons can be used for image generation. However, it is also possible for mirror ions/mirror electrons to be used as second individual particle beams, i.e. first individual particle beams undergoing reversal directly upstream of or at the object.

The disclosure involves effecting defocused projecting of the second individual particle beams onto detection regions of a detection unit in such a way that the second individual particle beams emerging or emanating from two different individual field regions are projected onto different detection regions, wherein a plurality of detection channels are assigned to each detection region, wherein the detection channels each encode angle information and/or direction information of the second individual particle beams when starting from the object. In the case, too, of the defocused projecting of the second individual particle beams onto detection regions of a detection unit, crosstalk between the second individual particle beams can thus avoided, just as is already known from operating a multi-beam particle microscope in a normal operating mode/inspection mode. However, the defocusing can enlarge the actual incidence regions and thus the detection regions per second individual particle beam. As a result, information present in the angular spectrum of the second individual particle beams can be maintained during detection. It is desirable to provide a plurality of detection channels, this can be for example two, three, four, five, six or more detection channels per detection region. These detection channels have the property, then, that they each encode angle information and/or direction information of the second individual particle beams when starting from the object. Specifically, the second individual particle beams are incident on different detection channels depending on the starting direction and/or the starting angle. Spatially resolved detection takes place. Reference can be made to direction-sensitive detection for example if the detection channels are arranged such that the incidence of particles of the second individual particle beams can be subdivided into, for example, at the top, at the bottom, on the left and on the right (corresponding to four sectors) or else obliquely at the top left, obliquely at the top right or centrally at the bottom (three sectors). In this case, the detection channels can be formed by sectorization of detection regions. In this context, the term detection channel then relates to the incidence surface of the detection region. However—depending on context—the term detection channel can also encompass the signal evaluation in the course of detection. Specifically, a signal is generated separately, in general, for each detection channel. For each detection region, therefore, a plurality of signals are generated from the corresponding plurality of detection channels. Angle information about the second individual particle beams when starting from the object can be obtained for example by way of radially sensitive detection channels, for example via circular or concentrically ring-shapedly arranged channels (example of a shell-like construction). In accordance with an embodiment, the detection channels allow both direction information and angle information to be encoded; they are then direction-sensitive and radially sensitive. Examples of this are set out in even greater detail further below.

According to the disclosure, generating individual images of each of the individual field regions takes place on the basis of data which are obtained or have been obtained via signals from each of the detection regions with their respectively assigned detection channels. Therefore, the generation of individual images is not just influenced wholesale by the signals from each of the detection regions by way of mere addition of all the signals of the detection channels of the entire detection region, rather the individual images are generated by using signals from each of the detection channels per detection region according to a suitable algorithm. In this case, it is possible to generate the individual images practically immediately, but it is also possible to store the data and to generate the individual images therefrom only later. As a result, it also becomes possible to obtain different individual images for different contrast modes on the basis of data or signals, once present.

In accordance with an embodiment of the disclosure, the method according to the disclosure furthermore includes the following steps in the contrast operating mode: defining weightings for signals from each detection channel; and mixing the signals from the detection channels to form a mixed signal of the assigned detection region on the basis of the weightings.

It is thus possible, depending on the objective, to weight the signals from each detection channel differently and thereby to take account of the spatial resolution of the signals. Angle information and/or direction information can be processed accordingly. Mixing the signals makes it possible for signals from different detection channels to be added or subtracted from one another in a targeted manner, for example. It is also possible to determine average values or median values; maxima or minima can likewise be determined. Therefore, depending on the issue, the mixed signal of a detection region is constituted on the basis of the signals of its detection channels. The technique of mixing signals is known in general. More detailed explanations in this respect may be found for example in U.S. Pat. No. 10,192,716 B2 and also U.S. Pat. No. 10,186,399 B2. Simple basic principles concerning angle-dependent detection of secondary electrons in a single-beam system are also already known from the textbook by Ludwig Reimer, “Scanning Electron Microscopy”, Springer-Verlag Berlin Heidelberg 1985, 1998.

In accordance with an embodiment of the disclosure, the method furthermore includes the following step in the contrast operating mode: selecting a contrast aperture which has been or is arranged in the secondary path of the multi-beam particle microscope in the region of a beam cross-over of the second individual particle beams.

The contrast aperture can be for example a circular aperture or a ring aperture, a bright field aperture or a dark field aperture. It is possible to provide not just one but rather a plurality of identical or different contrast apertures through which the second individual particle beams pass successively. It is possible for the contrast aperture already to be situated in the beam path of the second individual particle beams and for the selection to take place by the second individual particle beams being deflected accordingly. This can be done for example via a parallel offset of the second individual particle beams in the secondary path. However, it is also possible for a contrast aperture only to be introduced into the beam path, for example moved or rotated into the desired position. Selecting a contrast aperture can then comprise moving a specifically selected contrast aperture (or contrast apertures) into the beam path. Different contrast apertures can differ for example in terms of their diameter and/or their annular width. In any case the contrast aperture or contrast stop has the task of filtering second individual particle beams according to their starting angles from the object plane. Second individual particle beams proceeding from/up to a specific starting angle range are cut out from the pencil of the second individual particle beams in the beam cross-over. Further details concerning the significance of the contrast aperture and also concerning the possible configurations thereof can be gathered for example from the German patent application with the application number 10 2020 123 567.4, filed on Sep. 9, 2020, and the German patent DE 2015 202 172 B4, the disclosure of which is in each case fully incorporated by reference in the present patent application.

In accordance with an embodiment of the disclosure, the method furthermore includes the following step in the contrast operating mode: setting the defocusing of the second individual particle beams upon incidence on the detection unit, for example on the basis of the selected contrast aperture. As a result, the defocusing chosen can be of a greater or lesser degree. Angle information and/or direction information of the second individual particle beams can be detected in a more detailed way, the greater the degree of defocusing is chosen. Conversely, however, the signal per detection channel then also becomes weaker and the area of the detection unit increases with the same number of individual particle beams being used. Depending on the information and/or configuration of the detection unit, the defocusing can thus be selected accordingly. This can be carried out manually by a user, but it is also possible for the setting of the defocusing to be carried out automatically on the basis of known or stored parameters regarding the sample/inspection aim. The setting of the defocusing itself can be carried out by way of corresponding control of the projection lens system in the secondary path of the multi-beam particle beam microscope.

In accordance with an embodiment of the disclosure, the method furthermore comprises the following step in the contrast operating mode: selecting a number of detection channels per detection region.

In this case, selecting a number of detection channels can, but need not, be coupled to the set defocusing. This is dependent, inter alia, on the physical realization of the detection unit. It is possible, for example, for the detection unit to be constructed overall from a multiplicity of detection channels. In a normal operating mode, for example, a detection region can then be assigned to each detection channel or correspond thereto. In the contrast operating mode, on the other hand, a plurality of detection channels are combined to form a detection region. In this case, the detection unit as such is not altered physically, just the assignment of the detection channels to a detection region changes. Selecting a number of detection channels per detection region increases the flexibility of the method according to the disclosure. The greater the number of angle- and/or direction-sensitive detection channels used per detection region, the greater the amount of angle- and/or direction-sensitive information that can be obtained during imaging. In one extreme case, all available detection channels can be combined to form a detection region—however, the imaging is then also based only on a single individual particle beam and the method is accordingly slower. In most practical applications, therefore, a considerable proportion of all the individual particle beams, e.g. approximately one third, quarter or fifth of all available individual particle beams, will then be used for imaging and be caused to be incident on the detector in a defocused fashion. In another extreme case, all available individual particle beams can be used for imaging and are incident on the detector in a defocused fashion. It is then desirable, however, for a correspondingly large number of detection channels to be kept available. This exemplary embodiment may be useful, for example, in the case of small contrast apertures and/or a large pitch of the first individual particle beams.

In accordance with an embodiment of the disclosure, the method furthermore comprises the following step in the contrast operating mode: setting a pitch of the second individual particle beams upon incidence on the detection unit on the basis of the selected contrast aperture and/or the set defocusing and/or the selected number of detection channels per detection region. In this case, the pitch of the second individual particle beams can be set for example such that out of available detection channels as few detection channels as possible remain unused. The total detection area of the detection unit may be used as optimally as possible as a result. Moreover, setting the pitch on the basis of the set defocusing can help ensure that different second individual particle beams are imaged onto different detection regions. If detection channels are not produced by interconnecting detection pixels, for example, but rather are physically separate and extremely small detection units, then setting a pitch is automatically accompanied by selecting a number of detection channels. It is thus possible for the parameters of number of detection channels, on the one hand, and magnitude of the pitch, on the other hand, not to be strictly independent of one another. Nevertheless, gaps between the defocused second individual particle beams can be present or set and detection channels present can therefore also remain unused.

Moreover, the total alignment of the defocused second individual particle beams with the detection unit can be performed such that center points of the individual particle beams are aligned substantially exactly with a detection channel or else substantially symmetrically centrally between incidence surfaces of detection channels. This last can be desirable for example given a number of three detection channels per detection region, wherein the three detection channels can have round incidence surfaces and can be arranged in a “triangular” fashion or close to one another as much as possible. Other shapes of incidence surfaces are also possible, for example hexagonal incidence surfaces.

The total alignment of the defocused second individual beams can be effected for example by a multi-beam deflector in the secondary path, for example via the so-called anti-scan upstream of the detection unit. It is thus possible for the second individual particle beams to be displaced in parallel fashion on the detection unit until the desired total alignment of the second individual particle beams is achieved.

The pitch itself can be set by way of a setting of the enlargement in the primary path and/or in the secondary path. It is also possible to use multi-aperture plates having different aperture arrangements or aperture spacings when producing the multiplicity of individual particle beams in the primary path.

In accordance with an embodiment of the disclosure, the method furthermore includes the following steps in the contrast operating mode: selecting a number of individual particle beams which are incident on the detection unit in the contrast operating mode; and/or masking out all other individual particle beams.

It is possible that only a single individual particle beam is intended to be incident on the detection unit. In another extreme case, all the individual particle beams are selected, but a corresponding number of detection channels is then be kept available. However, it is possible for two or more individual particle beams to be incident on the detection unit, for example approximately one third, one quarter or one fifth of all individual particle beams.

One objective when selecting the number of individual particle beams which are incident on the detector in a defocused fashion is that as many of the theoretically available detection channels as possible are also used for obtaining signals. If not enough detection channels are available or if the area of the detection unit is not large enough, then remaining or surplus individual particle beams may no longer be able to be incident on the detection unit or on detection channels. It may then be desirable for these as it were superfluous individual particle beams to be masked out in a targeted manner. In this case, the masking out can be effected in the primary path and/or in the secondary path. Optionally, it is already effected in the primary path, for example comparatively far up in the particle optical beam path shortly after the generation of the multiplicity of individual particle beams. By way of example, a beam selector can be provided in the particle optical beam path. Additionally or alternatively, it is also possible to concomitantly convey individual particle beams not used for the defocused detection and to bring about charging effects at the sample in a targeted manner by way of the beams.

In accordance with an embodiment of the disclosure, the method furthermore includes the following step: aligning the defocused second individual particle beams upon incidence on the detection unit in such a way that the chief rays of the second individual particle beams are aligned substantially exactly centrally with a detection channel; or aligning the defocused second individual particle beams upon incidence on the detection unit in such a way that the chief rays of the second individual particle beams are aligned substantially symmetrically centrally between incidence surfaces of detection channels.

The central alignment with a detection channel can be suitable for obtaining angle information since this alignment facilitates a shell-like arrangement of detection channels. The symmetrical alignment centrally between incidence surfaces can be desirable for obtaining direction information. However, that respectively does not preclude also additionally generating direction information or additionally generating angle information.

In accordance with an embodiment of the disclosure, the latter furthermore comprises the following step in the contrast operating mode: encoding the individual images in a false color code on the basis of signals from the detection regions and/or the detection channels. It is possible, for example, on the basis of the angle information and/or direction information used, to distinguish rising edges from falling edges by way of color coding. It is possible, for example, to represent upper and lower edges or left and right edges in different colors as a false color code. This facilitates the interpretation of the image data obtained.

In accordance with an embodiment of the disclosure, the method furthermore includes the following step in the contrast operating mode: representing the individual images in a perspective representation or in a 3D representation.

A perspective representation is occasionally also referred to as a 2.5D representation. Via a conventional 2D display mechanism, the perspective representation enables a good spatial impression of what is represented. A 3D representation can be attained for example via a 3D display such as, for example, via smartglasses or an augmented reality or virtual reality display, in which a user can move or change his/her perspective. Holographic representations are possible as well.

In accordance with an embodiment of the disclosure, the method furthermore comprises the following step in the contrast operating mode: providing an arrangement of detection channels which is direction-sensitive and/or radially sensitive. This arrangement of detection channels can be provided for each detection region. As a result, it is possible to obtain direction information and/or angle information of the second individual particle beams when starting from the object plane or the object during detection.

In accordance with an embodiment of the disclosure, the method furthermore comprises the following step: operating the multi-beam particle microscope in a normal inspection mode, comprising the following steps: irradiating the object with a multiplicity of charged first individual particle beams, wherein each first individual particle beam irradiates a separate individual field region of the object in a scanning fashion; collecting second individual particle beams which emerge or emanate from the object on account of the first individual particle beams; focused projecting of the second individual particle beams onto detection regions of a detection unit in such a way that the second individual particle beams emerging or emanating from two different individual field regions are projected onto different detection regions, wherein exactly one detection channel is assigned to each detection region; and generating individual images of each of the individual field regions on the basis of data which are obtained or have been obtained via signals from each of the detection regions with their respectively assigned detection channel.

Operating the multi-beam particle microscope in a normal inspection mode thus describes, in general, operating a multi-beam particle microscope as already known from the prior art. It can be desirable to use the conventional focused projecting of the second individual particle beams onto the detection unit. In this case, the detection unit used in the contrast operating mode can be the same detection unit that is also used in the normal inspection mode. However, the detection regions then have a different size and position and a different assignment of detection regions to detection channels takes place; in the normal inspection mode, each detection region is only assigned to a single detection channel.

In accordance with an embodiment of the disclosure, the method changes between operating the multi-beam particle microscope in the contrast operating mode and in the normal inspection mode. In this case, it is possible to alternate strictly between the two modes. However, it is also possible for example firstly for a relatively large sample region to be scanned in the normal inspection mode and subsequently for a plurality of partial regions of the sample to be scanned in the contrast operating mode. As a result, sample regions of particular interest can be examined more closely again in the contrast operating mode.

In accordance with an embodiment of the disclosure, various contrast operating modes with associated operating parameters are stored in a controller of the multi-beam particle microscope and the method furthermore includes the following step: selecting a contrast operating mode and operating the multi-beam particle microscope in this contrast operating mode. The various contrast operating modes can differ for example in the contrast apertures used, the set defocusing, the number of second individual particle beams that are incident on the detector or used for imaging in the contrast operating mode, the number of detection channels per detection region or per second individual particle beam, the beam current intensity of the individual particle beams, the landing energy, the beam pitch, the sample material, etc. The selectable contrast operating modes can then also include the following modes in an application-related manner: edge contrast operating mode, material contrast operating mode, charge contrast operating mode and also direction-edge contrast operating mode. Unlike in the conventional edge contrast operating mode, which only analyzes the presence of an edge, the direction-edge contrast operating mode makes it possible to distinguish between different types of edges with regard to their nature (rising edge, falling edge, left side, right side, etc.). This can involve, besides the angle information, also the direction information and thus the direction-sensitive detection of the second individual particle beams in the contrast operating mode.

The above-described embodiments of the disclosure can be combined with one another in full or in part, provided that no technical contradictions arise as a result.

In accordance with a second aspect, the disclosure provides a computer program product having a program code for carrying out the method as described above in a plurality of embodiment variants.

In accordance with a third aspect, the disclosure provides a multi-beam particle microscope comprising the following: a multi-beam particle source, which is configured to generate a first field of a multiplicity of charged first individual particle beams; a first particle optical unit with a first particle optical beam path, configured to image the generated first individual particle beams onto an object plane such that the first individual particle beams strike an object at incidence locations, which form a second field; a detection system with a multiplicity of detection regions that form a third field; a second particle optical unit with a second particle optical beam path, configured to image second individual particle beams, which emanate from the incidence locations in the second field, onto the third field of the detection regions of the detection system; a for example magnetic objective lens, through which both the first and the second individual particle beams pass; a beam switch, which is arranged in the first particle optical beam path between the multi-beam particle source and the objective lens and which is arranged in the second particle optical beam path between the objective lens and the detection system; a mode selection device configured to make a selection between a normal operating mode and a contrast operating mode; and a controller, wherein a beam cross-over of the second individual particle beams is arranged in the second particle optical beam path between the beam switch and the detection system, wherein a contrast aperture for filtering the second individual particle beams according to their starting angles from the object plane is arranged in the region of the beam cross-over, wherein the controller is configured to control the second particle optical unit in the normal operating mode in such a way that the second individual particle beams are incident on the detection regions substantially in a focused fashion, wherein in the normal operating mode each detection region is assigned exactly one detection channel for signal evaluation, and wherein the controller is configured to control the second particle optical unit in the contrast operating mode in such a way that at least one or some or all of the second individual particle beams are incident on the detection regions in a defocused fashion, wherein in the contrast operating mode each detection region is assigned a plurality of detection channels for signal evaluation, wherein each of the plurality of detection channels is arranged such that an angle-dependent and/or direction-dependent detection of second individual particle beams can take place in the contrast operating mode.

The multi-beam particle microscope according to the disclosure can be suitable for carrying out the described method according to the disclosure in accordance with the first aspect of the disclosure. In this case, the terms used for describing the multi-beam particle microscope correspond to those for describing the method according to the disclosure.

In accordance with an embodiment of the disclosure, the detection system comprises one or more particle detectors or the detection system consists of one or more particle detectors. In accordance with an embodiment, the detection system comprises one or more particle detectors and also a plurality of light detectors disposed downstream thereof. By way of example, the detection system can comprise as particle detector a scintillator plate having a plurality of detection regions and/or detection channels. In this case, the interaction products can be projected onto the detection regions/detection channels of the particle detector with the aid of a suitable particle optical unit, for example via a projection lens system and a collective scan deflector (so-called anti-scan). The light signals emitted by the particle detector can then pass in a suitable manner to a light detector assigned to the respective detection region or detection channel of the particle detector. It is possible, for example, for the light emitted by a detection region of the particle detector to be coupled into optical fibers via a corresponding light optical unit, the fibers in turn being connected to the actual light detector. The light detector can comprise for example a photomultiplier, a photodiode, an avalanche photodiode or other types of suitable light detectors. It is possible, for example, for a detection region together with an optical fiber assigned thereto and in turn together with a light detector assigned to the optical fiber to form a detection channel (in the signal sense). Alternatively, it is possible for a light detector not to comprise an optical fiber. It is possible, for example, to provide, instead of an optical fiber bundle, an array of light-sensitive detectors (e.g. photomultipliers, photodiodes, avalanche photodiodes, etc.) directly as signal entrance surface. In this case, as it were, each optical fiber is replaced by one or more light detector pixels.

In accordance with an alternative embodiment of the disclosure, the detection system consists of one or more particle detectors. In other words, the detection system then comprises one or more particle detectors, but no light detectors. It is then possible to detect the secondary individual particle beams directly, without the detour via photons, for example by their being injected into the depletion layer of a semiconductor, whereby once again an electron avalanche can then be initiated. This then involves a correspondingly structured semiconductor detector comprising at least one independent conversion unit for each beam.

In accordance with an embodiment of the disclosure, each detection channel comprises exactly one optical fiber and different detection channels comprise different optical fibers. In other words, a one-to-one assignment is present here. It is true that the prior art also discloses optical fibers which are multi-channel and transfer different signals separately for example by way of a sectorial construction of the optical fiber. However, here the unwanted mixing/mode coupling of different channels currently still poses a challenge; however, by way of example, partial or gradual mixing between detection channels which are to be assigned to the same detection region may be acceptable.

By virtue of the assignment—already described above—of detection regions of a particle detector to specific detection channels or light detectors and, in concrete terms, to the signal entrance surface of optical fiber bundles, the geometric configuration of the signal entrance surface also acquires further significance. The way in which the optical fibers are arranged or packed in relation to one another is to be considered. For a good resolution, it can be desirable to pack the optical fibers with their respective signal entrance surfaces as close to one another as possible.

In accordance with an embodiment of the disclosure, each detection channel has a signal entrance surface that is circular or triangular or hexagonal. The triangular case can involve an isosceles triangle or an equilateral triangle. The signal entrance surface can be the incidence surface on a particle detector or else an incidence surface for photons on an optical fiber. In the case of a detection system comprising one or more particle detectors and also a plurality of light detectors disposed downstream thereof, each channel thus optionally has two signal entrance surfaces, namely in one instance for particle detection and later also in another instance for light detection. For at least one signal entrance surface, the criterion of circular or triangular is satisfied in accordance with this embodiment variant; it can be satisfied for light detection.

In accordance with an embodiment of the disclosure, the signal entrance surfaces of the detection channels have a hexagonally close packed arrangement and/or the signal entrance surfaces are arranged overall as a hexagon. This hexagonally close packed arrangement and/or the arrangement overall as a hexagon can be attained for example with the above-described circular or triangular or hexagonal signal entrance surface of the detection channels. However, it is also possible for the signal entrance surfaces of the detection channels to be rectangular or square and for the signal entrance surfaces overall to give rise to a rectangle or square. Other geometric shapes are also conceivable, although the complexity during signal evaluation then increases.

In accordance with an embodiment of the disclosure, exactly three or exactly four or exactly six detection channels are assigned to a detection region in the contrast operating mode. In the case of exactly three detection channels, the signal entrance surface of each detection channel can be circular or hexagonal, for example, and the three detection channels are “triangular” and have a close packed arrangement relative to one another. This arrangement can help allow direction-sensitive detection for each detection channel. If exactly four detection channels are assigned to a detection region, this can be realized for example by four congruent right-angled isosceles triangles arranged overall as a square. The corners of the triangles thus meet at the center point of the square. In this embodiment, too, a direction sensitivity is easily possible by virtue of the four sectors. If a detection region comprises exactly six detection channels, then these six detection channels can be realized for example by six equilateral triangles arranged overall as a hexagon. This embodiment variant also can help ensure the direction sensitivity. However, it is also possible, of course, to choose other forms of arrangement, for example exactly four detection channels, the signal entrance surfaces of which are embodied in each case as squares, the four detection channels then overall likewise being arranged as a square.

In accordance with an embodiment of the disclosure, at least two shells of a concentric shell-like arrangement of signal entrance surfaces are assigned to a detection region in the contrast operating mode. This shell-like concentric arrangement of signal entrance surfaces makes it possible to obtain radially sensitive information or angle information, optionally in addition to obtaining direction-sensitive information. In this case, the inner shell includes information about a central angular range and thus a relatively steep incidence of beams on the detector; the second shell encompasses larger angular deviations and hence a shallower incidence of the beams on the detection surface. It is possible to provide exactly two shells, but it is also possible to provide more than two shells.

In accordance with an embodiment of the disclosure, the arrangement of the signal entrance surfaces of the detection channels is hexagonal and the innermost shell comprises exactly one, exactly seven or exactly nineteen detection channels. In this case, the individual signal entrance surfaces of the detection channels are circular or hexagonal, for example, and the innermost shell comprises for example one central detection channel and six further detection channels arranged annularly or hexagonally around it, or, in the case of a total of nineteen detection channels, twelve further detection channels are again arranged around the described 1+6=7 detection channels.

In accordance with an embodiment of the disclosure, the arrangement of the signal entrance surfaces of the detection channels is hexagonal and the innermost shell comprises exactly six or exactly 24 detection channels. The signal entrance surfaces are then embodied for example in the form of equilateral triangles. In the case of exactly six detection channels as the innermost shell, these six triangular signal entrance surfaces then have the six-fold rotational symmetry around the center point formed by a corner of the triangles. In the case of exactly 24 detection channels, the described hexagonal unit of six is used to construct a larger hexagon with a total of 24 detection channels.

In accordance with an embodiment of the disclosure, the arrangement of the signal entrance surfaces of the detection channels is rectangular and the innermost shell comprises exactly one, exactly nine or exactly sixteen detection channels. In the case of exactly nine detection channels, for example nine rectangles or squares are arranged relative to one another such that they in turn give rise to a rectangle or square. In the case of exactly sixteen detection channels, additional seven detection channels are again arranged around the rectangle of nine or square of nine, thus resulting in a larger rectangle or square.

It is also possible for groups of detection channels to be connected to one another, for example laser-welded to one another. This can contribute to minimizing a signal loss that would otherwise result from incidence of secondary particles between detection channels. Connecting or for example laser welding is possible for example if the connected or laser-welded detection channels are each to be assigned to the same detection region. Crosstalk between the detection channels that possibly occurs as a result of the connection is then less or not disturbing at all.

Further geometric configurations which are useful for practical application will be evident to the person skilled in the art.

The described embodiments in accordance with the third aspect of the disclosure can be combined with one another in full or in part, provided that no technical contradictions arise as a result.

It is also possible for the embodiments in accordance with the first, second and/or third aspects of the disclosure to be combined with one another in full or in part, provided that no technical contradictions arise as a result.

### BRIEF DESCRIPTION OF THE DRAWINGS

The disclosure can be understood even better with reference to the accompanying figures, in which:

FIG. 1 shows a schematic illustration of a multi-beam particle microscope (MSEM);

FIGS. 2A-2B schematically show detection systems of a multi-beam particle microscope;

FIGS. 3A-3B schematically compare the effect of an angular distribution of second individual particle beams in the case of focused and defocused detection;

FIGS. 4A-4D illustrate an application example for the disclosure (edge contrast);

FIGS. 5A-5B illustrate an application example for the disclosure (voltage contrast);

FIG. 6 schematically shows detection of focused secondary beams in a normal inspection mode;

FIG. 7 schematically shows detection of defocused secondary beams in a contrast operating mode;

FIG. 8 schematically shows detection of defocused secondary beams with three detection channels per detection region;

FIG. 9 schematically shows detection of defocused secondary beams with seven detection channels per detection region;

FIGS. 10A-10G schematically illustrate various geometries of detection regions and detection channels;

FIG. 11 schematically illustrates a geometry of detection regions and detection channels;

FIGS. 12A-12B schematically illustrate various geometries of detection regions and detection channels;

FIG. 13 schematically illustrates a geometry of detection regions and detection channels;

FIGS. 14A-14C schematically show embodiments for detection regions and detection channels; and

FIG. 15 shows an exemplary workflow in which the method according to the disclosure is used.

### DETAILED DESCRIPTION

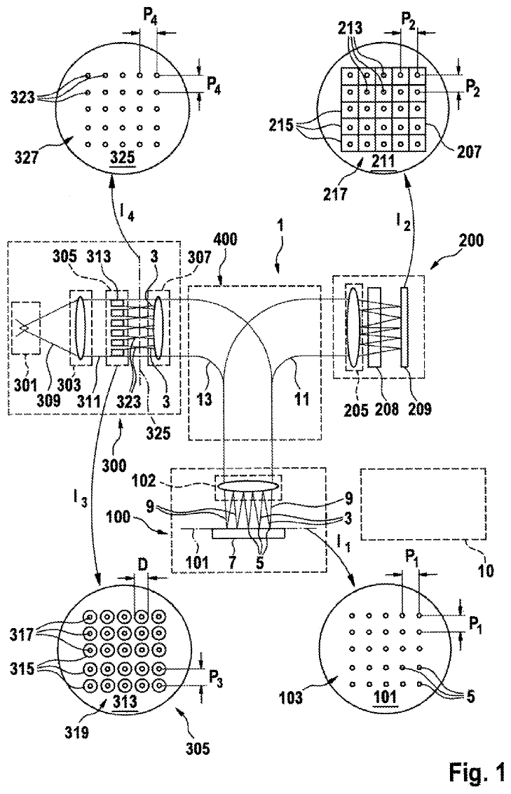

FIG. 1 is a schematic illustration of a particle beam system 1 in the form of a multi-beam particle microscope 1, which uses a multiplicity of particle beams. The particle beam system 1 generates a multiplicity of particle beams which are incident on an object to be examined in order to generate there interaction products, e.g. secondary electrons, which emanate from the object and are subsequently detected. The particle beam system 1 is of the scanning electron microscope (SEM) type, which uses a plurality of primary particle beams 3 which are incident on a surface of the object 7 at a plurality of locations 5 and produce there a plurality of electron beam spots, or spots, that are spatially separated from one another. The object 7 to be examined can be of any desired type, e.g. a semiconductor wafer or a biological sample, and comprise an arrangement of miniaturized elements or the like. The surface of the object 7 is arranged in a first plane 101 (object plane) of an objective lens 102 of an objective lens system 100.

The enlarged detail I1 in FIG. 1 shows a plan view of the object plane 101 having a regular rectangular field 103 of incidence locations 5 formed in the first plane 101. In FIG. 1, the number of incidence locations is 25, which form a 5×5 field 103. The number 25 of incidence locations is a number chosen for reasons of simplified illustration. In practice, the number of beams, and hence the number of incidence locations, can be chosen to be significantly greater, such as, for example, 20×30, 100×100 and the like.

In the illustrated embodiment, the field 103 of incidence locations 5 is a substantially regular rectangular field having a constant spacing P1 between adjacent incidence locations. Exemplary values of the spacing P1 are 1 micrometer, 10 micrometers and 40 micrometers. However, it is also possible for the field 103 to have other symmetries, such as a hexagonal symmetry, for example.

A diameter of the beam spots shaped in the first plane 101 can be small. Exemplary values of the diameter are 1 nanometer, 5 nanometers, 10 nanometers, 100 nanometers and 200 nanometers. The focusing of the particle beams 3 for shaping the beam spots 5 is carried out by the objective lens system 100.

The primary particles incident on the object generate interaction products, e.g. secondary electrons, backscattered electrons or primary particles that have experienced a reversal of movement for other reasons and which emanate from the surface of the object 7 or from the first plane 101. The interaction products emanating from the surface of the object 7 are shaped by the objective lens 102 to form secondary particle beams 9. The particle beam system 1 provides a particle beam path 11 for guiding the plurality of secondary particle beams 9 to a detector system 200. The detector system 200 comprises a particle optical unit with a projection lens 205 for directing the secondary particle beams 9 at a particle multi-detector 209.

The detail 12 in FIG. 1 shows a plan view of the plane 211, in which individual detection regions of the particle multi-detector 209 on which the secondary particle beams 9 are incident at locations 213 are located. The incidence locations 213 lie in a field 217 with a regular spacing P2 from one another. Exemplary values of the spacing P2 are 10 micrometers, 100 micrometers and 200 micrometers.

The primary particle beams 3 are generated in a beam generating apparatus 300 comprising at least one particle source 301 (e.g. an electron source), at least one collimation lens 303, a multi-aperture arrangement 305 and a field lens 307. The particle source 301 generates a diverging particle beam 309, which is collimated or at least substantially collimated by the collimation lens 303 in order to shape a beam 311 which illuminates the multi-aperture arrangement 305.

The detail 13 in FIG. 1 shows a plan view of the multi-aperture arrangement 305. The multi-aperture arrangement 305 comprises a multi-aperture plate 313, which has a plurality of openings or apertures 315 formed therein. Midpoints 317 of the openings 315 are arranged in a field 319 that is imaged onto the field 103 formed by the beam spots 5 in the object plane 101. A spacing P3 between the midpoints 317 of the apertures 315 can have exemplary values of 5 micrometers, 100 micrometers and 200 micrometers. The diameters D of the apertures 315 are smaller than the distance P3 between the midpoints of the apertures. Exemplary values of the diameters D are 0.2×P3, 0.4×P3 and 0.8×P3.

Particles of the illuminating particle beam 311 pass through the apertures 315 and form particle beams 3. Particles of the illuminating beam 311 which are incident on the plate 313 are absorbed by the latter and do not contribute to the formation of the particle beams 3.

On account of an applied electrostatic field, the multi-aperture arrangement 305 focuses each of the particle beams 3 in such a way that beam foci 323 are formed in a plane 325. Alternatively, the beam foci 323 can be virtual. A diameter of the beam foci 323 can be, for example, 10 nanometers, 100 nanometers and 1 micrometer.

The field lens 307 and the objective lens 102 provide a first imaging particle optical unit for imaging the plane 325, in which the beam foci 323 are formed, onto the first plane 101 such that a field 103 of incidence locations 5 or beam spots arises there. Should a surface of the object 7 be arranged in the first plane, the beam spots are correspondingly formed on the object surface.

The objective lens 102 and the projection lens arrangement 205 provide a second imaging particle optical unit for imaging the first plane 101 onto the detection plane 211. The objective lens 102 is thus a lens that is part of both the first and the second particle optical unit, while the field lens 307 belongs only to the first particle optical unit and the projection lens 205 belongs only to the second particle optical unit.

A beam switch 400 is arranged in the beam path of the first particle optical unit between the multi-aperture arrangement 305 and the objective lens system 100. The beam switch 400 is also part of the second optical unit in the beam path between the objective lens system 100 and the detector system 200.

Further information relating to such multi-beam particle beam systems and components used therein, such as, for instance, particle sources, multi-aperture plate and lenses, can be obtained from the international patent applications WO 2005/024881 A2, WO 2007/028595 A2, WO 2007/028596 A1, WO 2011/124352 A1 and WO 2007/060017 A2 and the German patent applications DE 10 2013 016 113 A1 and DE 10 2013 014 976 A1, the disclosure of which is fully incorporated by reference in the present application.

The multiple particle beam system furthermore comprises a computer system 10 configured both for controlling the individual particle optical components of the multiple particle beam system and for evaluating and analyzing the signals obtained using the multi-detector 209 or the detection unit 209. It can also be used to carry out the method according to the disclosure. The computer system 10 can be constructed from a plurality of individual computers or components.

In the illustration in accordance with FIG. 1, the second individual particle beams 9 impinge on the detection plane 211 in a focused fashion. This illustration or this kind of operation corresponds to the already known operation of a multi-beam particle microscope in a normal operating mode or in a normal inspection mode. During operation of the multi-beam particle microscope in accordance with the method according to the disclosure, which method comprises operating the microscope in a contrast operating mode, the incidence of the second individual particle beams on the detection plane 211 changes; the incidence takes place in a defocused fashion in the contrast operating mode. This will be explained in even greater detail below.

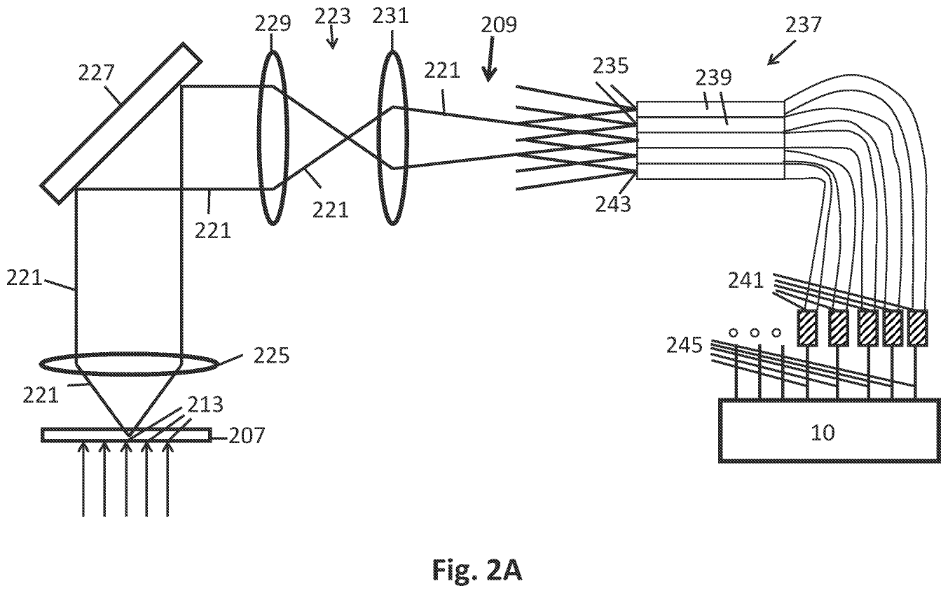

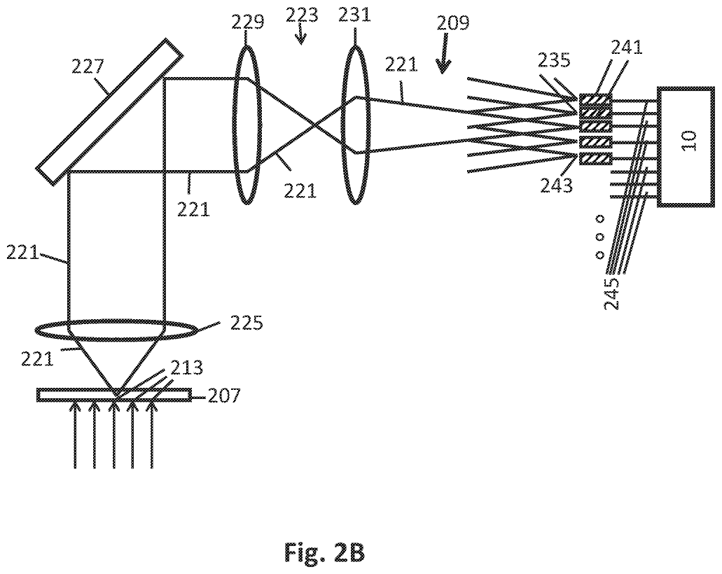

FIG. 2A is a schematic illustration for elucidating a realization of the detector 209 by way of example; reference is initially made once again to the normal operating mode. In this case, the detector 209 comprises a scintillator plate 207 as particle detector, onto which scintillator plate the interaction products, for example secondary electron beams, are directed by an electron optical unit, the electron optical unit comprises, if it is integrated into the multi-beam particle microscope from FIG. 1, the electron optical components of the particle optical unit which shape the electron beams 9, i.e. e.g. the objective lens 102, which direct the electron beams 9 toward the detector 209, such as e.g. the beam switch 400, and which focus the electron beams 9 on the surface of the scintillator plate 207, such as e.g. the lens 205. The electron beams 9 are incident on the scintillator plate 207 at incidence locations 213. Even if the electron beams 9 are focused on the surface of the scintillator plate 207, beam spots having diameters that are not arbitrarily small are formed on the surface. The midpoints of the beam spots can be regarded as the incidence locations 213, which are arranged at the distance P2 (cf. FIG. 1) from one another.

The scintillator plate 207 contains a scintillator material, which is excited to emit photons by the incident electrons of the electron beams 9. Each of the incidence locations 213 thus forms a source of photons. FIG. 2A illustrates just a single corresponding beam path 221 emanating from the incidence location 213 of the central electron beam of the five electron beams 9 illustrated. The beam path 221 passes through a light optical unit 223, which comprises a first lens 225, a mirror 227, a second lens 229 and a third lens 231 in the example shown, and then impinges on a light receiving surface 235 (signal entrance surface 235) of a light detection system 237. The light receiving surface 235 is formed by an end face of an optical fiber 239, into which at least a portion of the photons is coupled and guided to a light detector 241. The light detector 241 can comprise e.g. a photomultiplier, an avalanche photodiode, a photodiode or other types of suitable light detectors. The light optical unit 223 is configured such that it optically images the surface 208 of the scintillator plate 207 into a region 243 in which the light receiving surface 235 is arranged. On account of this optical imaging, optical images of the incidence locations 213 are generated in the region 243. In the region 243, a separate light receiving surface 235 of the light detection system 237 is provided for each of the incidence locations 213. Each of the further light receiving surfaces 235 (signal entrance surfaces 235) is formed by an end face of a light guide 239, which guides the light coupled into the end face to a light detector 241. On account of the optical imaging, a light receiving surface 235 is assigned to each of the incidence locations 213, wherein the light entering a respective light receiving surface 235 is detected by a separate light detector 241. The light detectors 241 output electrical signals via signal lines 245, the electrical signals represent intensities of the particle beams 9. Consequently, the locations on the surface of the scintillator plate 207 which are imaged onto the light receiving surfaces of light detectors 241 define different detection points or detection regions. On account of the electron optical unit described above, interaction products, for example electrons, which emanate from two different individual field regions of an object are also projected onto different detection regions of the scintillator plate 207. In the exemplary embodiment explained here, the light detectors 241 are arranged at a distance from the light receiving surfaces 235, onto which the light optical unit 223 images the scintillator plate 207, and the received light is guided to the light detectors 241 through optical fibers 239. However, it is also possible for the light detectors 241 to be arranged directly where the light optical unit generates the image of the scintillator plate and the light-sensitive surfaces of the light detectors thus form the light receiving surfaces.

In this case, FIG. 2A merely schematically elucidates some details of the detector 209. It should still be pointed out at this juncture that by virtue of the scanning movement of the primary particle beams over an object or a sample, many points of the sample are irradiated or scanned. In this case, each primary particle beam 3 sweeps wholly or partly over an individual field region of the object. In this case, each primary particle beam 3 is allocated a dedicated individual field region of the object. From these individual field regions of the object 7, interaction products, e.g. secondary electrons, then in turn emanate from the object 7. The interaction products are then projected onto the detection regions of the particle detector or onto the scintillator plate 207 in such a way that the interaction products emanating from two different individual field regions are projected onto different detection regions of the scintillator plate 207. Light signals are emitted by each detection region of the scintillator plate 207 upon incidence of the interaction products, e.g. secondary electrons, on the detection region, wherein the light signals emitted by each detection region are fed to a light detector 241 assigned to the respective detection region. In other words, the situation is that each primary particle beam 3 comprises its own detection region on the scintillator 207 and also its own light detector 241, which together form a detection channel in the normal inspection mode.

In the contrast operating mode, the second individual particle beams 9 are incident on the scintillator plate 207 in a defocused fashion. The detection area impinged on by a particle beam 9 increases as a result of the defocusing; the detection region 215 assigned to the particle beam 9 grows in size. However, the optical imaging of the emerging photons onto the light receiving surfaces 235 remains unchanged, in general, such that for each second individual beam 9 photons now pass into a plurality of light receiving surfaces 235 or optical fibers with connected light detectors 241. In other words, a plurality of detection channels 235 are assigned to a detection region 215 defined relative to an individual particle beam.

FIG. 2B shows an alternative embodiment variant of a detection system 209. In this variant, no optical fibers 239 are provided; instead, photons emanating from the scintillator plate 207, after the optical imaging, impinge directly on an array having light-sensitive detectors 241, for example an array comprising photomultipliers, photodiodes or avalanche photodiodes.

Detection architectures other than the ones illustrated in FIG. 2A and FIG. 2B are also suitable for carrying out the method according to the disclosure for operating a multi-beam particle microscope 1 in a normal operating mode and in the contrast operating mode according to the disclosure. Reference is made, for example, to the method of DED (“direct electron detection”), which manages without light detectors and in which secondary electrons are directly converted into a current signal.

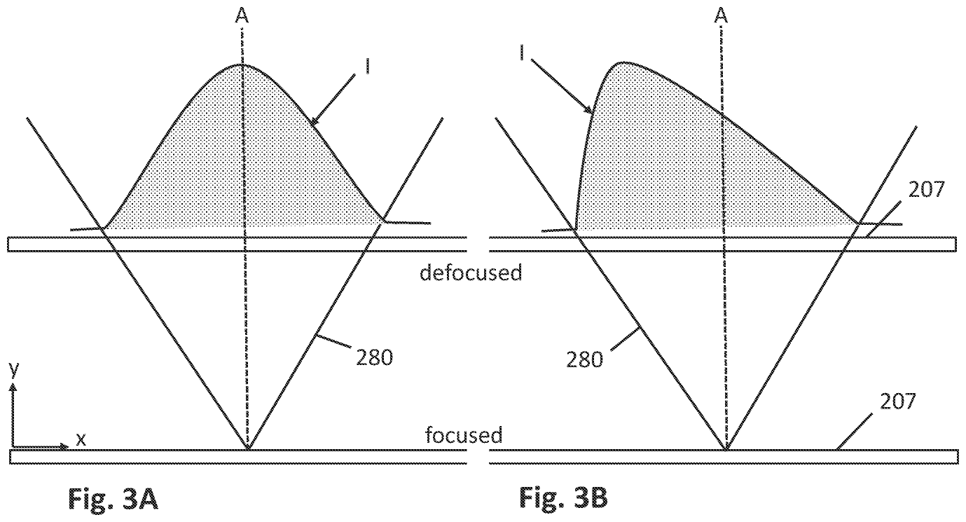

FIG. 3 schematically compares the effect of an angular distribution of second individual particle beams 9 in the case of focused and defocused detection. FIG. 3 illustrates two different case situations: In case a, it is assumed that second individual particle beams 9 that emanated from a flat sample 7 are detected. The second individual particle beams 9 start isotropically from the sample. In case b, it is assumed that second individual particle beams 9 or secondary beams emanated from a structured sample 7. The second individual particle beams start from the sample anisotropically, i.e. with an anisotropic direction distribution and/or angle distribution. The illustration in FIG. 3 then shows the two different cases during detection:

In case a, during detection the angle distribution of the secondary electrons is symmetrical about the axis A arranged orthogonally to the detection plane. The secondary electron yield, designated by I, is plotted on the Y-axis in FIG. 3a. Furthermore, the beam cone 280 is depicted schematically. The focused incidence of secondary beams on the detection surface 207 is illustrated at the bottom of the depiction in FIG. 3a, and the defocused incidence is illustrated at the top in the figure. In the case of focused incidence on the detection surface 207, no additional information about the angle distribution of the second individual particle beams is obtained; it is practically lost during focused detection. In the defocused case, on the other hand, the angle distribution of the second individual particle beams is present and, during detection, it is reproduced in the spatial distribution on the detector or the detection surface 207.

In the case of a flat sample, the secondary electron yield is isotropic about the axis A and, in the case of a structured sample, the secondary electron yield 1 is anisotropic, the maximum being to the left of the axis A of symmetry in the example shown. In general, therefore, defocused detection of secondary beams makes it possible to obtain angle information and/or direction information of the second individual particle beams 9 when starting from an object 7. It becomes accessible as a result of spatially resolved detection of the secondary beams 9 or assigned photons with the use of light detectors 241.

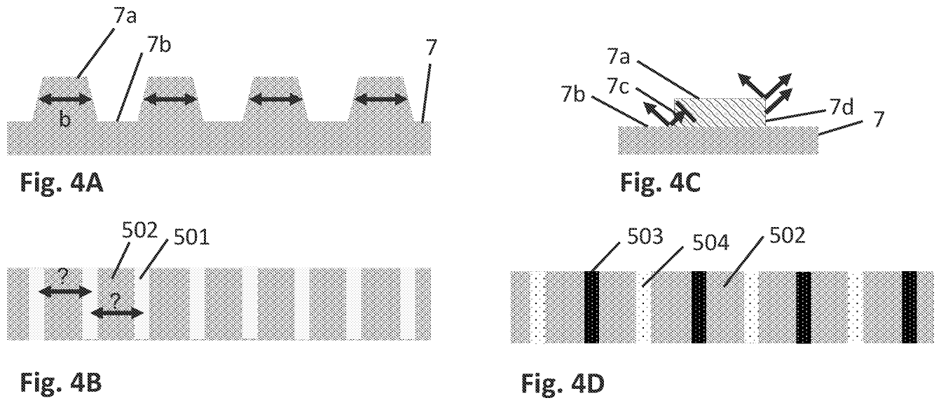

FIG. 4 illustrates one application example for the disclosure. In this case, FIG. 4A shows a structured sample 7 in a side view, elevations 7a and depressions 7b being arranged alternately in the sample. The width of an elevation 7a is designated by b. This width b often has to be determined during an inspection of semiconductor samples. The underlying issue concerns so-called edge contrast (topography contrast). An associated electron-optically obtained image is shown in FIG. 4B: During this recording, the imaging of the secondary electron beams onto the detector 209 is effected in a focused fashion. As a result, the image in accordance with FIG. 4B shows alternately wide strips 502 and narrow strips 501. However, during focused imaging it is not possible to differentiate whether a wide strip 502 is to be assigned to an elevation 7a or to a depression 7b.

By comparison therewith, the situation is different when using a contrast operating method according to the disclosure for the multi-beam particle microscope 1: FIG. 4C schematically shows a structured sample 7 and the emergence of secondary beams or second individual particle beams 9 from the sample 7. The secondary particles are illustrated by the arrows in FIG. 4C. The situation at the left edge 7c of the sample 7 will be considered first: Secondary electrons 9 starting from the sample 7 at the edge 7c have an angle distribution. Secondary electrons 9 starting toward the left may tend to start without being obstructed by the sample 7, and secondary electrons 9 initiated or starting toward the right tend to be shaded or absorbed by the elevation 7a of the sample 7. At the left edge 7c, therefore, the secondary electrons 9 tend to comprise more particles that start from the sample toward the left. The opposite situation arises at the edge 7d of the sample 7: Here secondary electrons 9 can also emerge from the lateral flank 7d, and the angular spectrum of the secondary electrons starting from the sample 7 therefore tends to comprise more secondary particles 9 deflected toward the right than secondary particles 9 deflected toward the left.

FIG. 4d then shows an electron optical recording in which the secondary beams have been detected in a defocused and spatially resolved fashion: By virtue of the use of angle information and/or direction information of the second individual particle beams 9 when starting from the object 7, the narrow regions 503 and 504 can be differentiated from one another in the recording: The strips 503 shown dark each correspond to a falling edge in FIG. 4A, and the light strips 504 each correspond to a rising edge in FIG. 4A. The use of the method according to the disclosure thus makes it possible to obtain improved contrast information, or contrast information not accessible hitherto in accordance with the prior art, when scanning a sample 7.

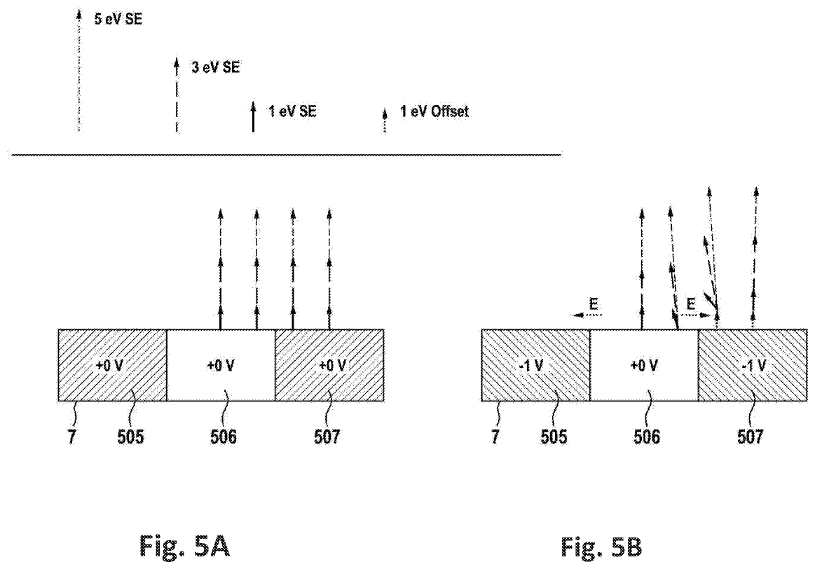

FIG. 5 illustrates a further application example for the disclosure, specifically in the case of examining charged samples. The examination of accumulations of charge on samples 7 takes place in the course of determining a so-called voltage contrast. The latter is of importance for example in the case of so-called electric response measurements. This is because some types of defects (resistance defects, leakage defects) cannot be detected by conventional inspection methods (focused detection). That is different in the case of defocused detection of second individual particle beams 9 and with the use of a plurality of spatially resolved detection channels per detection region. Specifically, the angular spectrum of the secondary electrons or second individual particle beams 9 starting from a sample changes in the case of accumulations of charge on the sample. This is illustrated in FIG. 5: FIG. 5A shows a sample 7 with different regions 505, 506 and 507, none of which is charged. Different secondary electrons emanate from these regions or the surface thereof; in this illustration, the secondary electrons start perpendicularly in each case and have different energies. In the example shown, these are electrons having 5 eV, 3 eV and 1 eV; the different energies are encoded by the different types of dashes used for the arrows in FIG. 5. Secondary electrons that start at other angles (not illustrated) are likewise influenced, and so an asymmetrical angle distribution of the secondary electrons arises according to the charge difference.

In FIG. 5B, the sample regions 505 and 507 are negatively charged, this being −1 V in the example illustrated. As a result, an electric field E is generated between the regions 505 and 506, and 506 and 507. The secondary electrons 9 starting from the sample are directionally deflected by the electric field E, and an offset additionally occurs at the negatively charged sample regions 505 and 507 (the offset is indicated by the short dashed arrow). The angular spectrum (location and/or direction information) of the secondary particles 9 emanating from the sample 7 thus changes as a result of the accumulation of charge on the sample 7. In the case of defocused detection, this information from the angular spectrum is transferred into location information and it is made measurable or usable during corresponding multi-channel measurement.

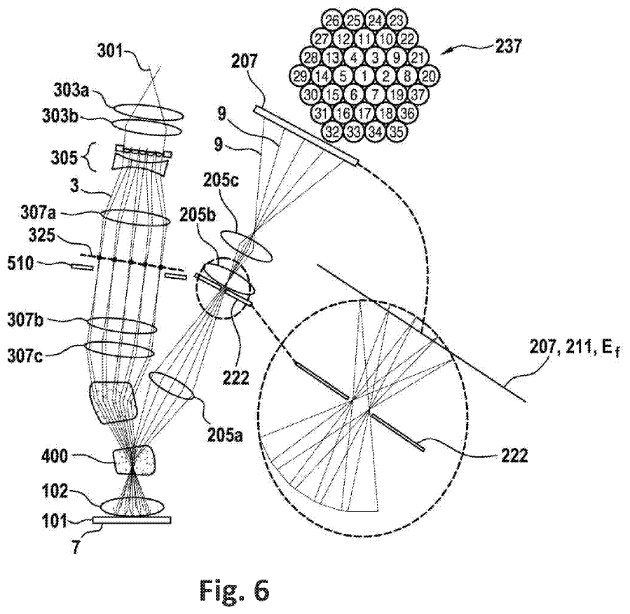

FIG. 6 schematically shows detection of focused secondary beams 9 in a normal inspection mode that is known from the prior art, in general. A particle source 301 emits a divergent particle beam, which, in the example shown, passes through a condenser lens system 303a, 303b and, in the example shown, impinges in a collimated fashion on a multi-beam particle generator 305 and passes through the latter. The generator can comprise for example a multi-aperture plate with a succeeding counterelectrode, but other embodiment variants are also possible. Theoretically it is also possible, of course, to use a multi-beam particle source 301 directly, such that the first individual particle beams 3 do not have to be formed separately by a multi-beam particle generator 305.

In the further particle optical beam path, in the example illustrated, the first individual particle beams 3 pass through a field lens system having the field lenses 307a, 307b and 307c. Afterward, they pass through a beam switch 400 and also a for example magnetic objective lens 102, and then the first individual particle beams 3 are incident in a focused fashion on the object 7 in the object plane 101. The incidence of the first individual particle beams 3 triggers the emergence of the second individual particle beams 9 from the sample or the object 7, the second individual particle beams likewise pass through the objective lens 102 and the beam switch 400 and also, in the example illustrated, subsequently a projection lens system 205a, 205b, 205c. In the projection lens system 205, a contrast aperture 222 is arranged in a beam cross-over of the second individual particle beams 9, the contrast aperture 222 can be a circular aperture or a ring aperture, for example. It can be a bright field aperture or a dark field aperture. The contrast aperture has the task of filtering second individual particle beams 9 according to their starting angles from the object plane 101. Second individual particle beams 9 proceeding from/up to a specific starting angle range are cut out from the pencil of the second individual particle beams 9 in the beam cross-over. This is illustrated schematically in the circle shown in an enlarged view in FIG. 6. The beam path in FIG. 6—as already explained—is illustrated only schematically and thus in a greatly simplified manner. In the normal inspection mode illustrated in FIG. 6, the second individual particle beams 9 are incident in a focused fashion on the detection plane 207 or the scintillator 207. Disposed downstream of the scintillator 207 is the light detector 237, which in FIG. 6 is illustrated schematically by the hexagonal arrangement of detection channels 1 to 37, the cross section or signal entrance surface 235 of which is configured here as a circle. In the case of the imaging illustrated in FIG. 6, the situation is such that the object plane 101 is imaged in a focused fashion onto the scintillator 207 or the plane E_{f}. Moreover, the situation is such that optionally all the individual particle beams 3, 9 are used for the imaging in order to achieve the highest possible throughput during the imaging.

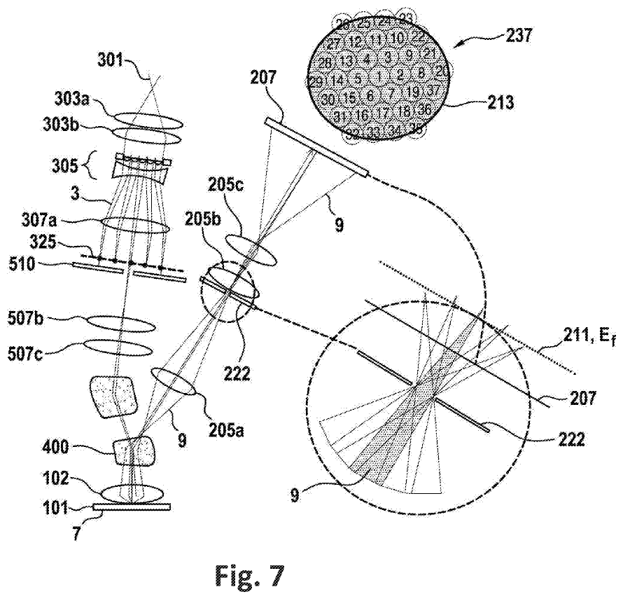

FIG. 7 then schematically shows detection of defocused secondary beams 9 in a contrast operating mode according to the disclosure of the multi-beam particle microscope 1. FIGS. 6 and 7 are largely identical to one another; hereinafter, therefore, only the differences of FIG. 7 compared with FIG. 6 are discussed. The secondary path in FIG. 7 is set for example via the projection lens system 205a, 205b, 205c such that the second individual particle beams 9 are incident in a defocused, rather than focused, fashion on the detection surface or, in the example shown, on the scintillator 207. In this case, FIG. 7 shows by way of example defocusing with the use of just one individual particle beam 9; in practice, a plurality of second individual particle beams can be used; even further explanations in this regard are given below. The second individual particle beam 9 passes through the contrast aperture 222 at the (theoretical) cross-over point between the second individual particle beams 9. The defocused individual particle beam 9 is then incident on the scintillator 207; by virtue of corresponding setting of the projection lens(es) 205b, 205c, the position of the detection plane/scintillator 207 is no longer identical to the position of the focal plane E_{f}. As a result of the defocusing, the incidence area of the second individual particle beam 9 on the detector also increases; in other words, the size of the detection region 215 changes. However, the physical detector 207, 209 is still the same; it can be spatially fixed. Therefore, photons released from the scintillator plate 207 now impinge on a plurality of detection channels of the light detector 237. FIG. 7 shows by way of example the illumination spot 213 when the photons are incident on the signal entrance surfaces/light receiving surfaces 235 of the optical fiber bundle of the light detector 237. However, it is also possible, of course, to use other detection systems. FIG. 7 merely shows the principle in this respect.

Moreover, in accordance with FIG. 7, it is possible to select a number of second individual particle beams 9 which are incident on the detection unit 207, 209 in the contrast operating mode, and to masking out all remaining individual particle beams. In the example shown, this is already done in the primary path via a beam selector 510. The latter can optionally mask out a single individual particle beam, two, three or any other number of individual particle beams 3 as early as in the primary path. Additionally or alternatively, it is also possible, in the secondary path, to mask out one or more second individual particle beams 9 from the secondary path.

Depending on the application, it is possible to set the defocusing of the second individual particle beams 9 upon incidence on the detection unit 209, for example on the basis of the selected contrast aperture. It is also possible to provide a plurality of contrast apertures successively. In addition, the contrast aperture can be moved into the beam path or provision can be made of a sectorized contrast aperture having different stops, through which the second individual particle beams can optionally pass. For this purpose, the sectorized contrast aperture can be mounted rotatably, for example, or it is possible to alter the path of the second individual particle beams accordingly in such a way as to pass through a specific sector.

Moreover, it is possible to select or fix a number of detection channels per detection region or per secondary particle beam 9. Additionally or alternatively, it is possible to set a pitch of the second individual particle beams 9 upon incidence on the detection unit 207, 209, for example on the basis of the selected contrast aperture 222 and/or the set defocusing and/or the selected number of detection channels 235 per detection region 215. Moreover, it is possible to operate the multi-beam particle microscope alternately in a normal inspection mode (focused detection) and in a contrast operating mode (defocused detection). It is possible that different contrast operating modes with associated operating parameters are stored in a controller 10 of the multi-beam particle microscope 1 and that one of the stored contrast operating modes is selected and the multi-beam particle microscope 1 is operated in this selected contrast operating mode.

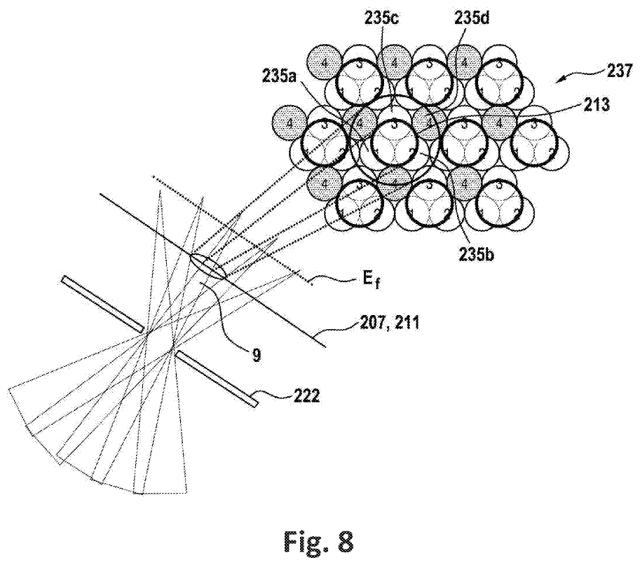

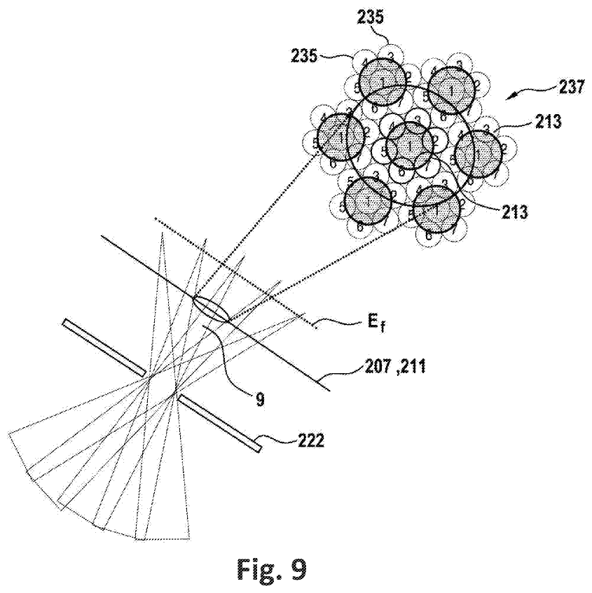

FIG. 8 schematically shows detection of defocused secondary beams 9 with three detection channels 235 per detection region 215. The illustration shows the projection from the particle detector, here a scintillator plate 207, onto a light detector 237 with the signal entrance surfaces 235 of an optical fiber bundle 239. The projection is indicated by the dotted lines in FIG. 8. The assignment of detection channels 235 to the optical fibers 237 is indicated by the numbering 1, 2, 3, 4. The numbers 1, 2, 3 denote active detection channels 235, and the number 4 denotes inactive detection channels 235. By way of example, 235a, 235b and 235c denote the three detection channels covered by the beam spot 213. FIG. 8 shows overall the detection of seven second individual particle beams 9. It additionally reveals that the beam spots 213 that are to be assigned to each of the second individual particle beams 9 do not overlap one another. Crosstalk between different detection regions 215 is avoided as a result. The beam pitch of the second individual particle beams 9 upon incidence on the detector 207 is set accordingly. It is possible to use the in general non-active detection channels 4 in the interspaces between the active detection channels 1, 2, 3 to detect the occurrence of possible crosstalk. Moreover, it is possible to use any signals that might arise in the detection channels 4 to check whether the alignment of the beams with the detector is correct. In the example shown, the center of the beams is aimed exactly at an intermediate region between the detection channels 1, 2 and 3. If a signal is then additionally detected in the channels 4, the alignment of the beams with the detector 209 is not optimal and is to be corrected. FIG. 9 schematically shows detection of defocused secondary beams 9 with seven detection channels 235 per detection region 215. In this case, the beam spots 213 of each beam are incident on seven signal entrance surfaces 235 of optical fibers 237. In the example shown, seven second individual particle beams 9 are in turn used for the detection. A hexagonal pattern of detection regions 215 arises overall in the example illustrated. For the rest, reference is made to the explanations regarding FIG. 8.

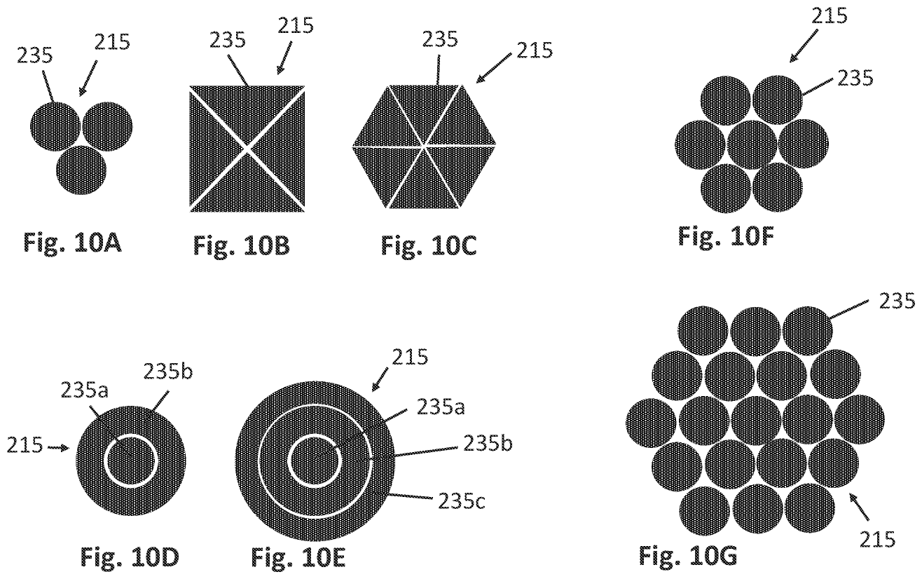

FIGS. 10A-10C schematically illustrates various geometries of detection regions 215 and detection channels 235. In this case, FIGS. 10A, 10B and 10C show detection regions 215, the detection channels 235 of which are arranged in a direction-sensitive manner. In accordance with the example in FIG. 10A, the detection channels 235 or the signal entrance surfaces 235 are circular, and the detection region 215 forms a triangle. In FIG. 10B, the detection channels 235 are embodied as isosceles triangles, the detection region 215 comprises four sectors and overall a square arises as the detection region 215.

FIG. 10C shows a hexagonal detection region 215 comprising six sectors, each channel 235 being formed by equilateral triangles 235.

FIGS. 10D and 10E show in each case radially sensitive arrangements of detection channels 235. In FIG. 10D, the innermost detection channel 235a is embodied as a circle. The annulus of the detection channel 235b is situated concentrically around the circle 235a. In FIG. 10E, a further annular detection channel 235c is situated concentrically around the other two detection channels 235a, 235b. Via the radially sensitive arrangement of detection channels 235 or via correspondingly constructed detection regions 215, it is possible to encode angle information of second individual particle beams 9 when starting from an object 7.

FIGS. 10F and 10G show a both direction-sensitive and radially sensitive arrangement of detection channels 235. In FIG. 10F, seven circular detection channels 235 are disposed in a close packed arrangement, thus resulting overall in a hexagonal arrangement of the detection channels 235. They can jointly form a detection region 215. FIG. 10G shows a further shell, in general: Here a further shell composed of detection channels 235 is arranged on the outside around the seven detection channels 235 from FIG. 10F. It is possible to interconnect the detection channels 235 to form an innermost shell with exactly seven detection channels and a further shell with a further twelve detection channels to form a detection region 215. However, other or extended combinations are also possible.

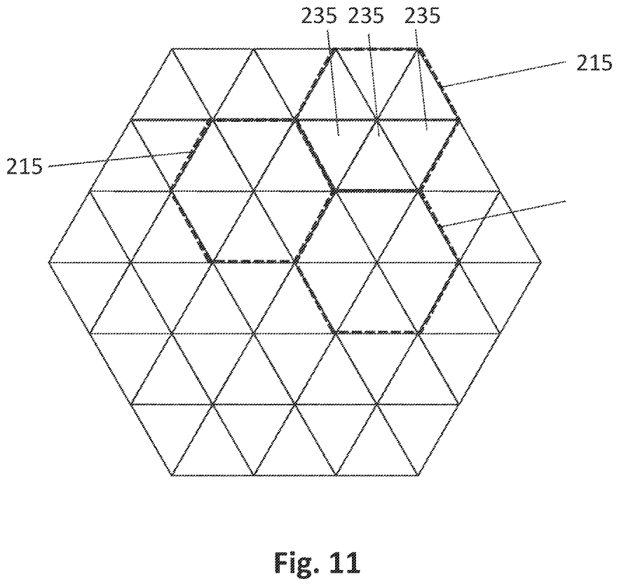

FIG. 11 schematically illustrates a further geometry of detection regions 215 and detection channels 235. In the example illustrated, the individual detection channels 235 are formed by equilateral triangles combined in each case to form hexagonal detection regions 215. The hexagonal detection regions 215 can in turn be put together altogether in such a way as to form a hexagonal overall arrangement; FIG. 11 here shows only a detail in this respect.

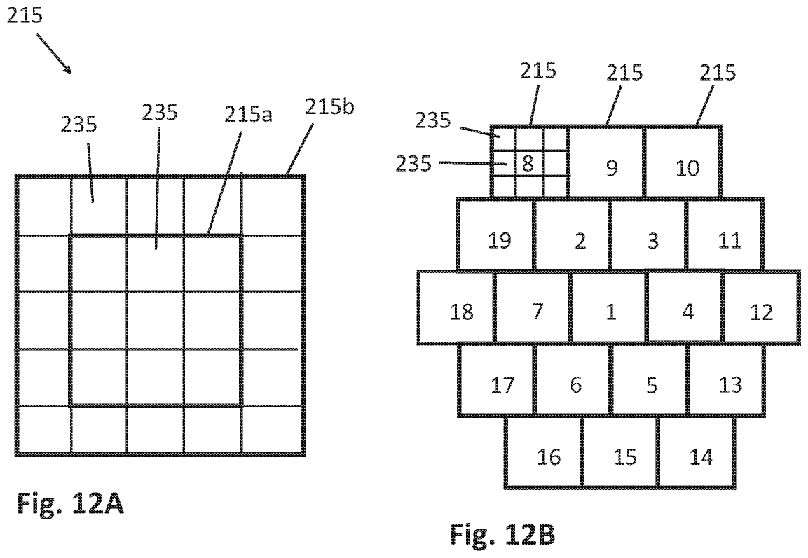

FIGS. 12A-12B schematically illustrate further various geometries of detection regions 215 and detection channels 235. In the example in accordance with FIG. 12A, the detection channels 235 are rectangular. In this case, nine rectangles form a detection region 215a. The latter can be regarded as the innermost shell in the case of a shell-like arrangement of detection regions 215. Exactly sixteen further detection channels 235 as a shell 215b are arranged around the innermost shell 215a. FIG. 12B shows a different arrangement of detection channels 235, which are likewise rectangular. The latter are combined in each case to form rectangular detection regions 215, which overall are arranged hexagonally. FIG. 12B shows by way of example nineteen detection regions 215, each of which is radially sensitive and direction-sensitive. However, other arrangements and combinations are also possible.

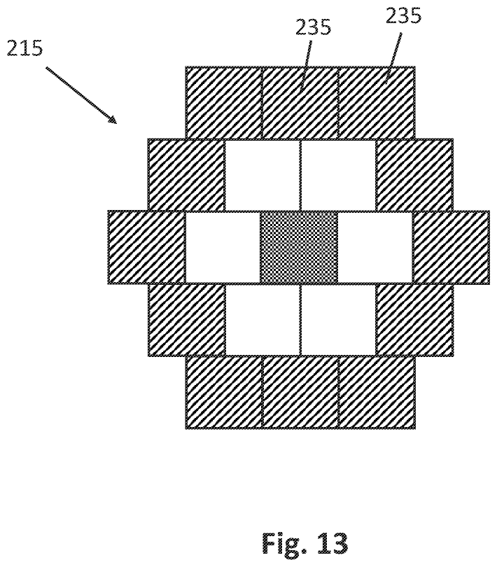

FIG. 13 schematically illustrates a further geometry of detection channels 235 of a detection region 215. In the example shown, the individual detection channels 235 are embodied as square or rectangular, and the detection region 215 overall is hexagonal. The different shadings in FIG. 13 illustrate a possible shell-like construction of the detection region 215.

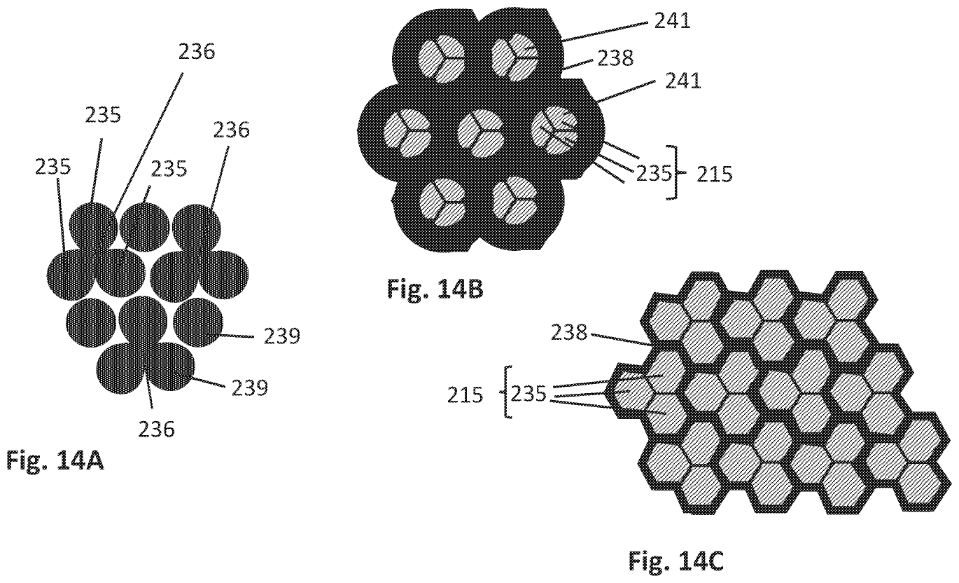

FIG. 14 schematically illustrates further embodiment variants for detection regions 215 and detection channels 235. FIG. 14A shows diverse optical fibers 239 having a round or drop-shaped signal entrance surface, which in each case form detection channels 235. In the example shown, three drop-shaped detection channels 235 are in each case connected to one another at the connection point 236, here via laser welding. In the example shown, only those detection channels 235 or optical fibers 239 which are to be assigned to the same detection region 215 in the contrast operating mode are connected to one another. Possible crosstalk between the connected detection channels therefore has hardly any effects on the overall signal of the detection region 215. Alternatively, however, it would also be possible for all the optical fibers 239 or detection channels 235 to be connected to one another or to be fused together at least at a seam, provided that resultant crosstalk is tolerable.

FIG. 14B schematically shows, as a light detection system, an array having light-sensitive detector units 241, which does not comprise any optical fibers 239 in the example shown. Instead, an array comprising photomultipliers, photodiodes or avalanche photodiodes or the like can be involved. The individual light detector units 241 are sectorized (here: three sectors or channels). Dead regions 238 between the light detector units 241 offer space for cabling, for example.

FIG. 14C schematically shows an arrangement of hexagonal detection channels 235. The latter can be joined together without gaps, in general, via tessellation. In the example shown, three detection channels are in each case combined to form a detection region 215. Dead regions 238 between the detection regions 215 serve for reducing crosstalk.

For all the detection regions 215 and detection channels 235 illustrated in FIGS. 10 to 14, it holds true that they can be assignable to a particle detector and/or to a light detector, even if many of the examples can be realized particularly well via a combination of particle detector with downstream light detector. The embodiment variants described should be understood not to be restrictive in this respect.

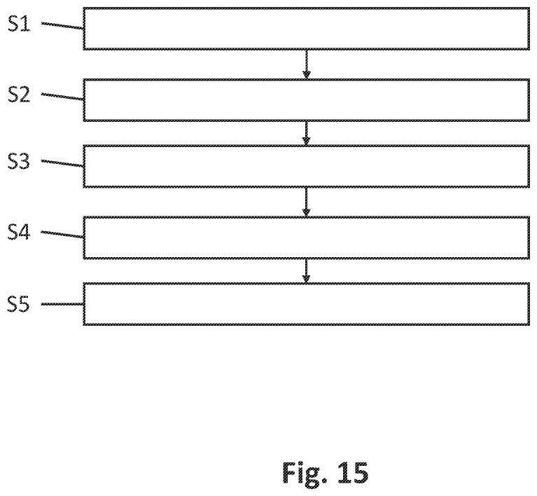

FIG. 15 shows by way of example a workflow in which the method according to the disclosure is used. A first method step S1 involves recording the sample in a contrast operating mode, with the use of only one defocused second individual particle beam or only a few defocused second individual particle beams with as many detection channels as possible per second individual particle beam. Such a contrast operating mode can also be referred to as a contrast review mode. This recording contains very much angle information and/or direction information, but is comparatively time-consuming.

In a further method step S2, contrast images of different types are represented on a graphical user interface, the contrast images are all based on the recording in the contrast review mode. The signals of the detection channels 23 are evaluated differently, however, thereby enabling different contrast information to be generated via one recording.

In a further step S3, e.g. via an input, a user of the multi-beam particle microscope can then mark one (or a plurality of) representation(s) of particular interest to the user. Step S3 thus involves selecting a contrast representation.

In a further method step S4, an algorithm stored in the controller, for example, calculates the operating parameters with which the selected contrast can be generated as rapidly as possible and/or in the best way. A contrast inspection task is thus optimized in step S4.

Step S5 involves recording the sample 7 with the optimized operating parameters. A user of the multi-beam particle microscope 1 can be optimally supported as a result.

### LIST OF REFERENCE SIGNS

1 Multi-beam particle microscope
3 Primary particle beams (individual particle beams)
5 Beam spots, incidence locations
7 Object, sample
7a Elevation
7b Depression
7c Edge, flank
7d Edge, flank
8 Sample stage
9 Secondary particle beams
10 Computer system, controller
11 Secondary particle beam path
13 Primary particle beam path
100 Objective lens system
101 Object plane
102 Objective lens
103 Field
110 Aperture
200 Detector system
205 Projection lens
207 Scintillator plate
208 Deflector for adjustment purposes
209 Detection system, particle multi-detector
211 Detection plane
213 Incidence locations, beam spot of the secondary particles or of the associated photon beam
215 Detection region
217 Field
221 Optical beam path
222 Contrast aperture
223 Light optical unit
225 Lens
227 Mirror
229 Lens
231 Lens
235 Light receiving surface, signal entrance surface, detection channel
236 Connection point
237 Light detection system
238 Dead region
239 Optical fiber, light guide
241 Light detector
243 Region for optical imaging of the scintillator surface
245 Line
280 Beam cone
300 Beam generating apparatus
301 Particle source
303 Collimation lens system
305 Multi-aperture arrangement
306 Micro-optics
307 Field lens system
309 Diverging particle beam
310 Multi-beam generator
311 Illuminating particle beam
313 Multi-aperture plate
314 Multi-field lens
315 Openings in the multi-aperture plate
317 Midpoints of the openings
319 Field
320 Multi-stigmator
323 Beam foci
325 Intermediate image plane
330 Multi-focus correction mechanism
380 Accumulation of positive charge
381 Accumulation of negative charge
400 Beam switch
501 Narrow strip
502 Wide strip
503 Dark strip for representing a falling edge
504 Light strip for representing a rising edge
505 Sample region
506 Sample region
507 Sample region
510 Beam selector
A Axis
Ef Focal plane
b Structure width
S1 Recording a sample with the fewest possible defocused second individual particle beams and as many detection channels as possible per second individual particle beam
S2 Generating and representing different contrast images
S3 Selecting a desired contrast or contrast image
S4 Optimizing the contrast inspection task
S5 Recording a sample with optimized operating parameters

1. A method, comprising:
operating a multi-beam particle microscope in a contrast operating mode, which comprises:
irradiating an object with a multiplicity of charged first individual particle beams, each first individual particle beam irradiating a separate individual field region of the object in a scanning fashion;
collecting second individual particle beams which emerge or emanate from the object due to the first individual particle beams;
defocused projecting the second individual particle beams onto detection regions of a detection unit so that the second individual particle beams emerging or emanating from two different individual field regions are projected onto different detection regions, a plurality of detection channels being assigned to each detection region, each detection channel encoding angle information and/or direction information of the second individual particle beams when starting from the object; and
generating individual images of each of the individual field regions on the basis of data which are obtained or have been obtained via signals from each of the detection regions with their respectively assigned detection channels.

2. The method of claim 1, wherein the contrast operating mode further comprises:
defining weightings for signals from each detection channel; and
mixing the signals from the detection channels to form a mixed signal of the assigned detection region based on the weightings.

3. The method of claim 1, wherein the contrast operating mode further comprises selecting a contrast aperture which has been or is arranged in a path of the second individual particle beams in a region of a beam cross-over of the second individual particle beams.

4. The method of claim 3, wherein the contrast operating mode further comprises setting the defocused projecting of the second individual particle beams upon incidence on the detection unit based on the selected contrast aperture.

5. The method of claim 1, wherein the contrast operating mode further comprises selecting a number of detection channels per detection region.

6. The method of claim 5, wherein the contrast operating mode further comprises setting a pitch of the second individual particle beams upon incidence on the detection unit based on at least one member selected from the group consisting of the selected contrast aperture, the set defocusing, and the selected number of detection channels per detection region.

7. The method of claim 1, wherein the contrast operating mode further comprises at least one of the following:
selecting a number of individual particle beams which are incident on the detection unit in the contrast operating mode; and
masking out all other individual particle beams.

8. The method of claim 1, wherein the contrast operating mode further comprises:
aligning the defocused second individual particle beams upon incidence on the detection unit so that chief rays of the second individual particle beams are aligned substantially exactly centrally with a detection channel; or
aligning the defocused second individual particle beams upon incidence on the detection unit so that the chief rays of the second individual particle beams are aligned substantially symmetrically centrally between incidence surfaces of detection channel.

9. The method of claim 1, wherein the contrast operating mode further comprises encoding the individual images in a false color code based on signals from at least one member selected from the group consisting of the detection regions and the detection channels.

10. The method of claim 1, wherein the contrast operating mode further comprises representing the individual images in a perspective representation or in a 3D representation.

11. The method of claim 1, wherein the contrast operating mode further comprises providing an arrangement of detection channels which comprises at least one member selected from the group consisting of direction-sensitive and radially sensitive.

12. The method of claim 1, further comprising operating the multi-beam particle microscope in a normal inspection mode, which comprises:
irradiating an object with a multiplicity of charged first individual particle beams, each first individual particle beam irradiating a separate individual field region of the object in a scanning fashion;
collecting second individual particle beams which emerge or emanate from the object due to the first individual particle beams;
focused projecting the second individual particle beams onto detection regions of a detection unit so that the second individual particle beams emerging or emanating from two different individual field regions are projected onto different detection regions, exactly one detection channel being assigned to each detection region; and
generating individual images of each of the individual field regions based on data which are obtained or have been obtained via signals from each of the detection regions with their respectively assigned detection channel.

13. The method of claim 12, further comprising changing between the contrast operating mode and the normal inspection mode.

14. The method of claim 1, wherein:
various contrast operating modes with associated operating parameters are stored in a controller of the multi-beam particle microscope; and
the method further comprises: selecting a contrast operating mode; and operating the multi-beam particle microscope in this contrast operating mode.

15. One or more machine-readable hardware storage devices comprising instructions that are executable by one or more processing devices to perform operations comprising the method of claim 1.

16. A system comprising:
one or more processing devices; and
one or more machine-readable hardware storage devices comprising instructions that are executable by the one or more processing devices to perform operations comprising the method of claim 1.

17. A multi-beam particle microscope, comprising:
a multi-beam particle source configured to generate a first field of a multiplicity of charged first individual particle beams;
a first particle optical unit with a first particle optical beam path configured to image the generated first individual particle beams onto an object plane so that the first individual particle beams strike an object at incidence locations, which form a second field;
a detection system comprising a multiplicity of detection regions that form a third field;
a second particle optical unit comprising a second particle optical beam path configured to image second individual particle beams which emanate from the incidence locations in the second field onto the third field of the detection regions of the detection system;
a magnetic objective lens configured to have the first and second individual particle beams pass therethrough;
a beam switch in the first particle optical beam path between the multi-beam particle source and the objective lens, the beam switch in the second particle optical beam path between the objective lens and the detection system;
a mode selection device configured to select between a normal operating mode and a contrast operating mode; and
a controller,
wherein:
a beam cross-over of the second individual particle beams is in the second particle optical beam path between the beam switch and the detection system;
a contrast aperture to filter the second individual particle beams according to their starting angles from the object plane is in a region of the beam cross-over;
the controller is configured to control the second particle optical unit in the normal operating mode so that the second individual particle beams are incident on the detection regions substantially in a focused fashion;
in the normal operating mode each detection region is assigned exactly one detection channel for signal evaluation;
the controller is configured to control the second particle optical unit in the contrast operating mode so that at least one second individual particle beam is incident on the detection regions in a defocused fashion;
in the contrast operating mode each detection region is assigned a plurality of detection channels for signal evaluation;
each detection channels is configured so that an angle-dependent and/or direction-dependent detection of second individual particle beams takes place in the contrast operating mode.

18. The multi-beam particle microscope of claim 17, wherein the detection system comprises at least one particle detector.

19. The multi-beam particle microscope of claim 17,
wherein the detection system comprises one or more particle detectors and also a plurality of light detectors disposed downstream thereof.

20. (canceled)

21. (canceled)

22. (canceled)

23. The multi-beam particle microscope of claim 17, wherein each detection channel comprises a signal entrance surface that is circular or triangular or hexagonal.

24. (canceled)

25. The multi-beam particle microscope of claim 17, wherein three or four or six detection channels are assigned to a detection region in the contrast operating mode.

26. The multi-beam particle microscope of claim 17, wherein at least two shells of a concentric shell-like arrangement of signal entrance surfaces are assigned to a detection region in the contrast operating mode.

27. (canceled)

28. (canceled)

29. (canceled)
